(19) United States
(12) Patent Application Publication
(10) Pub. No.: US 2010/0140593 A1
(43) Pub. Date: Jun. 10, 2010

(54) ORGANIC THIN-FILM TRANSISTORS

(75) Inventors: Yiliang Wu, Oakville (CA); Ah-Mee Hor, Mississauga (CA); Yuning Li, Singapore (CA); Ping Liu, Mississauga (CA); Paul F. Smith, Oakville (CA)

Correspondence Address: FAY SHARPE / XEROX - ROCHESTER, 1228 EUCLID AVENUE, 5TH FLOOR, THE HALLE BUILDING, CLEVELAND, OH, 44115, US

(73) Assignee: XEROX CORPORATION, Norwalk, CT (US)

(21) Appl. No.: 12/331,591

(22) Filed: Dec. 10, 2008

(51) Int. Cl. H01L 51/30; C07F 7/28; C07F 13/00; H01L 51/40; C07F 15/02

(52) U.S. Cl. 257/40; 548/402; 438/99; 257/E51.027

(57) ABSTRACT

A thin-film transistor has a semiconducting layer which comprises a halogen-coordinated metal phthalocyanine complex of Formula (I) or Formula (II):

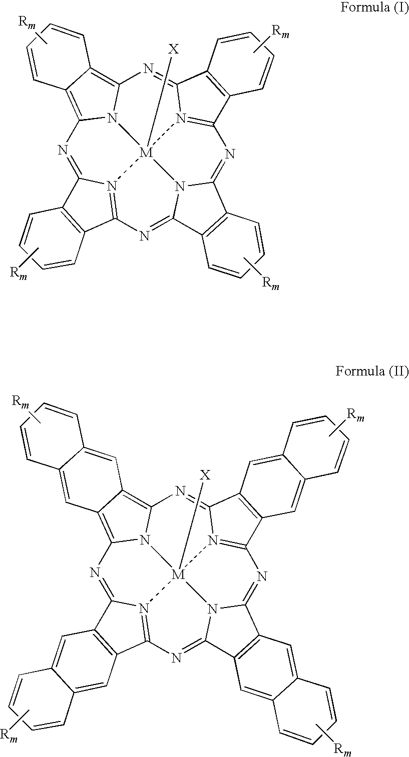

wherein M is a trivalent metal atom; each m represents the number of R substituents on the phenyl or naphthyl ring, and is independently an integer from 0 to 6; each R is independently selected from the group consisting of halogen, alkyl, substituted alkyl, alkoxy, substituted alkoxy, phenoxy, phenylthio, aryl, substituted aryl, heteroaryl, —CN, and —NO₂; and X is a halogen atom.

### BACKGROUND

The present disclosure relates, in various embodiments, to compositions and processes suitable for use in electronic devices, such as thin film transistors (“TFT”s). The present disclosure also relates to components or layers produced using such compositions and processes, as well as electronic devices containing such materials.

Thin film transistors (TFTs) are fundamental components in modern-age electronics, including, for example, sensors, image scanners, and electronic display devices. TFT circuits using current mainstream silicon technology may be too costly for some applications, particularly for large-area electronic devices such as backplane switching circuits for displays (e.g., active matrix liquid crystal monitors or televisions) where high switching speeds are not essential. The high costs of silicon-based TFT circuits are primarily due to the use of capital-intensive silicon manufacturing facilities as well as complex high-temperature, high-vacuum photolithographic fabrication processes under strictly controlled environments. It is generally desired to make TFTs which have not only much lower manufacturing costs, but also appealing mechanical properties such as being physically compact, lightweight, and flexible. Organic thin film transistors (OTFTs) may be suited for those applications not needing high switching speeds or high densities.

TFTs are generally composed of a supporting substrate, three electrically conductive electrodes (gate, source and drain electrodes), a channel semiconducting layer, and an electrically insulating gate dielectric layer separating the gate electrode from the semiconducting layer.

It is desirable to improve the performance of known TFTs. Performance can be measured by at least three properties: the mobility, current on/off ratio, and threshold voltage. The mobility is measured in units of cm²/V·sec; higher mobility is desired. A higher current on/off ratio is also desired. Threshold voltage relates to the bias voltage needed to be applied to the gate electrode in order to allow current to flow. Generally, a threshold voltage as close to zero (0) as possible is desired.

### BRIEF DESCRIPTION

The present disclosure is directed, in various embodiments, to a thin film transistor having a semiconducting layer comprising a specific genus of semiconducting material.

Disclosed in embodiments is a thin-film transistor comprising a semiconducting layer, wherein the semiconducting layer comprises a halogen-coordinated metal phthalocyanine complex of Formula (I) or Formula (II):

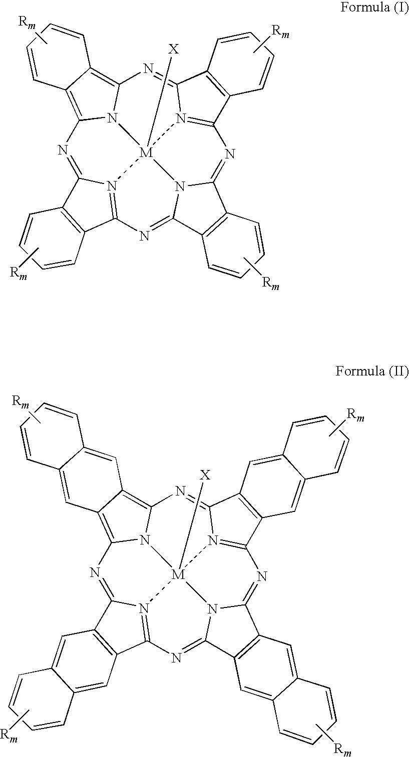

wherein M is a trivalent metal atom; each m represents the number of R substituents on the phenyl or naphthyl ring, and is independently an integer from 0 to 6; each R is independently selected from the group consisting of halogen, alkyl, substituted alkyl, alkoxy, substituted alkoxy, phenoxy, phenylthio, aryl, substituted aryl, heteroaryl, —CN, and —NO₂; and X is a halogen atom.

M may be selected from the group consisting of indium, antimony, iron, titanium, manganese, gallium, and aluminum. In specific embodiments, the halogen atom X is chlorine. In other specific embodiments, the trivalent metal atom M is indium, the halogen atom X is chlorine, and each m is zero.

Specific phthalocyanine complexes include those of Formulas (1)-(11):

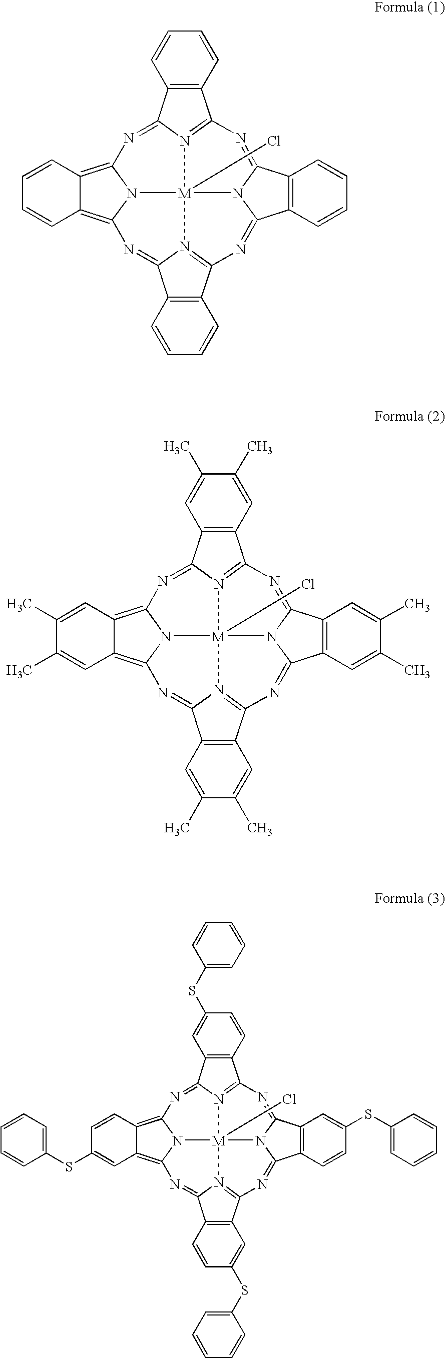

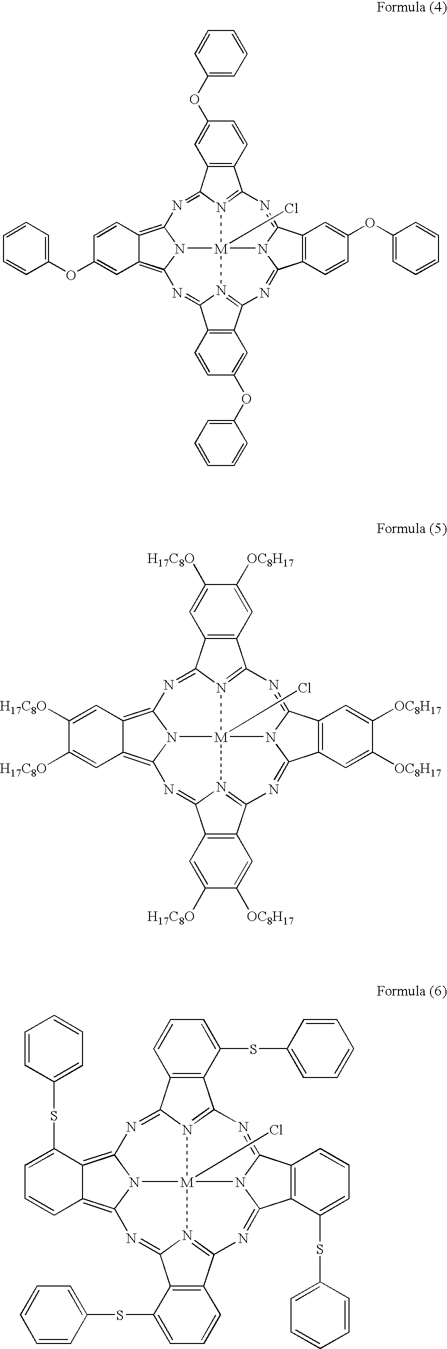

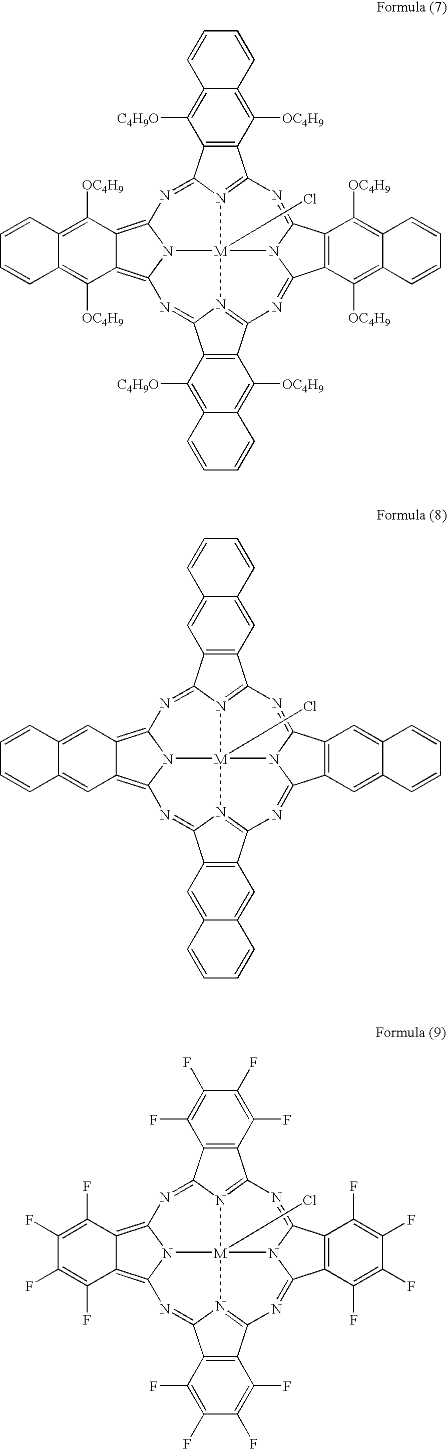

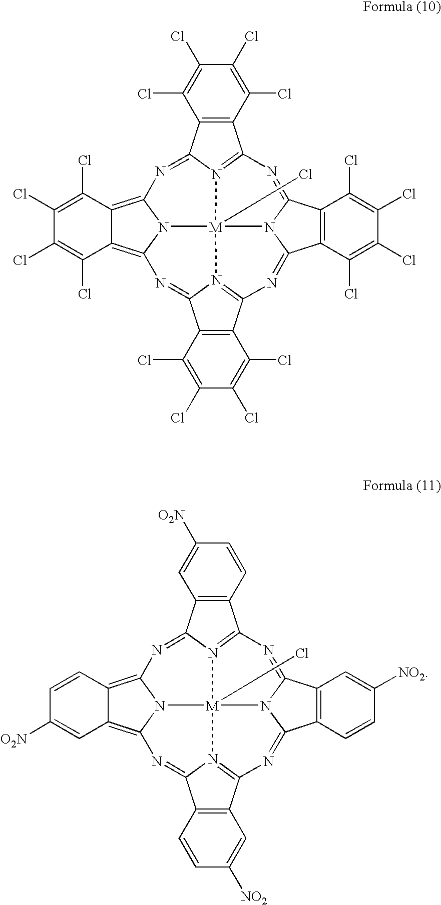

The transistor may have a mobility of about 0.1 cm²/V·sec or greater, and/or a current on/off ratio of about 10⁴ or greater.

The semiconducting layer may further comprise a polymer, such as one selected from the group consisting of triarylamine polymers, polyindolocarbazole, polycarbazole, polyacenes, polyfluorene, polystyrene, polymethyl methacrylate, poly(vinyl cinnamate), poly(vinyl phenol), polycarbonate, polythiophene, and polythiophene derivatives.

The transistor may further comprise an interfacial layer located between the semiconducting layer and a dielectric layer. The interfacial layer may be formed from an alkyltrichlorosilane having from about 4 to about 24 carbon atoms.

The halogen-coordinated metal phthalocyanine complex may form a two-dimensional interlocking structure.

Also disclosed in embodiments is a process of preparing a thin film transistor comprising: depositing a liquid composition onto a substrate to form a semiconducting layer, the liquid composition comprising a solvent, a polymer, and a halogen-coordinated metal phthalocyanine complex of Formula (I) or Formula (II):

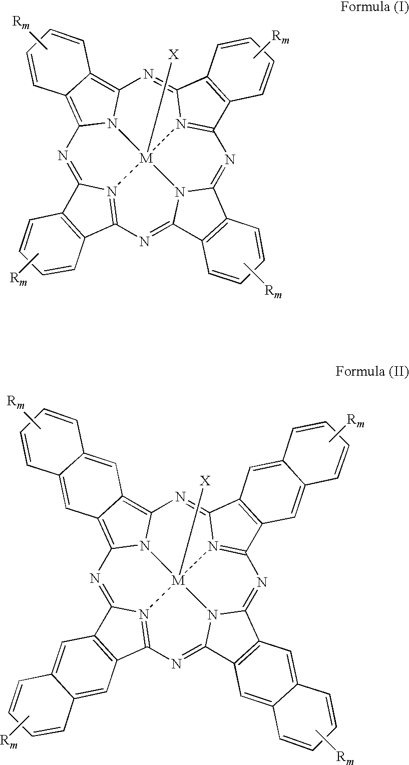

wherein M is a trivalent metal atom; each m represents the number of R substituents on the phenyl or naphthyl ring, and is independently an integer from 0 to 6; each R is independently selected from the group consisting of halogen, alkyl, substituted alkyl, alkoxy, substituted alkoxy, phenoxy, phenylthio, aryl, substituted aryl, heteroaryl, —CN, and —NO₂; and X is a halogen atom.

The halogen-coordinated metal phthalocyanine complex may be partially dissolved in the solvent and partially dispersed in the solvent. The weight ratio between the dissolved portion and the dispersed portion of the metal phthalocyanine complex may be from about 5:95 to about 80:20. The partially dispersed portion of the halogen-coordinated metal phthalocyanine complex may have a particle size of from about 10 nanometers to about 2000 nanometers.

The halogen-coordinated metal phthalocyanine complex and the polymer may be dissolved in the solvent.

The solvent may be a chlorinated solvent selected from the group consisting of chlorobenzene, dichlorobenzene, trichlorobenzene, and chlorotoluene.

Also included in further embodiments are the semiconducting layers and/or thin film transistors produced by this process.

These and other non-limiting characteristics of the exemplary embodiments of the present disclosure are more particularly described below.

### BRIEF DESCRIPTION OF THE DRAWINGS

The following is a brief description of the drawings, which are presented for the purpose of illustrating the exemplary embodiments disclosed herein and not for the purpose of limiting the same.

FIG. 1 is a first exemplary embodiment of a TFT of the present disclosure.

FIG. 2 is a second exemplary embodiment of a TFT of the present disclosure.

FIG. 3 is a third exemplary embodiment of a TFT of the present disclosure.

FIG. 4 is a fourth exemplary embodiment of a TFT of the present disclosure.

FIG. 5 is a graph showing the results of a TFT of the present disclosure.

### DETAILED DESCRIPTION

A more complete understanding of the components, processes, and apparatuses disclosed herein can be obtained by reference to the accompanying figures. These figures are merely schematic representations based on convenience and the ease of demonstrating the present development and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings and are not intended to define or limit the scope of the disclosure. In the drawings and the following description below, it is to be understood that like numeric designations refer to components of like function.

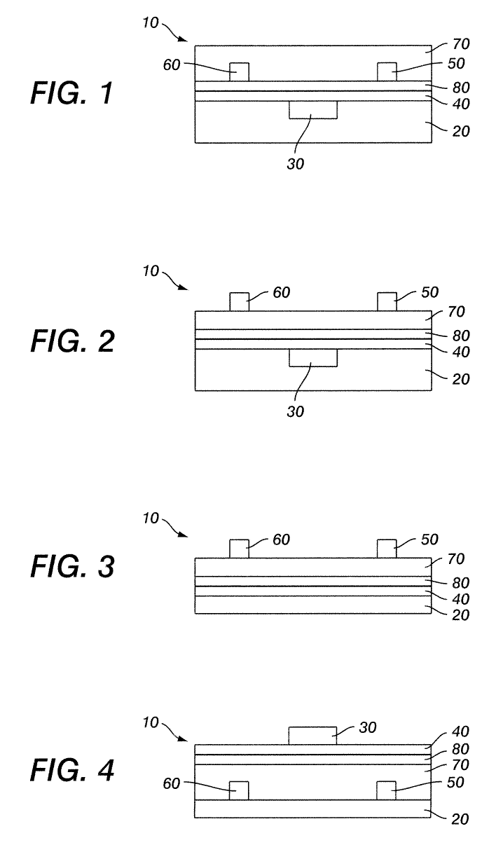

FIG. 1 illustrates a first OTFT embodiment or configuration. The OTFT 10 comprises a substrate 20 in contact with the gate electrode 30 and a dielectric layer 40. Although here the gate electrode 30 is depicted within the substrate 20, this is not required. However, of some importance is that the dielectric layer 40 separates the gate electrode 30 from the source electrode 50, drain electrode 60, and the semiconducting layer 70. The source electrode 50 contacts the semiconducting layer 70. The drain electrode 60 also contacts the semiconducting layer 70. The semiconducting layer 70 runs over and between the source and drain electrodes 50 and 60. Optional interfacial layer 80 is located between dielectric layer 40 and semiconducting layer 70.

FIG. 2 illustrates a second OTFT embodiment or configuration. The OTFT 10 comprises a substrate 20 in contact with the gate electrode 30 and a dielectric layer 40. The semiconducting layer 70 is placed over or on top of the dielectric layer 40 and separates it from the source and drain electrodes 50 and 60. Optional interfacial layer 80 is located between dielectric layer 40 and semiconducting layer 70.

FIG. 3 illustrates a third OTFT embodiment or configuration. The OTFT 10 comprises a substrate 20 which also acts as the gate electrode and is in contact with a dielectric layer 40. The semiconducting layer 70 is placed over or on top of the dielectric layer 40 and separates it from the source and drain electrodes 50 and 60. Optional interfacial layer 80 is located between dielectric layer 40 and semiconducting layer 70.

FIG. 4 illustrates a fourth OTFT embodiment or configuration. The OTFT 10 comprises a substrate 20 in contact with the source electrode 50, drain electrode 60, and the semiconducting layer 70. The semiconducting layer 70 runs over and between the source and drain electrodes 50 and 60. The dielectric layer 40 is on top of the semiconducting layer 70. The gate electrode 30 is on top of the dielectric layer 40 and does not contact the semiconducting layer 70. Optional interfacial layer 80 is located between dielectric layer 40 and semiconducting layer 70.

The semiconducting layer comprises a halogen-coordinated metal phthalocyanine complex of Formula (I) or Formula (II):

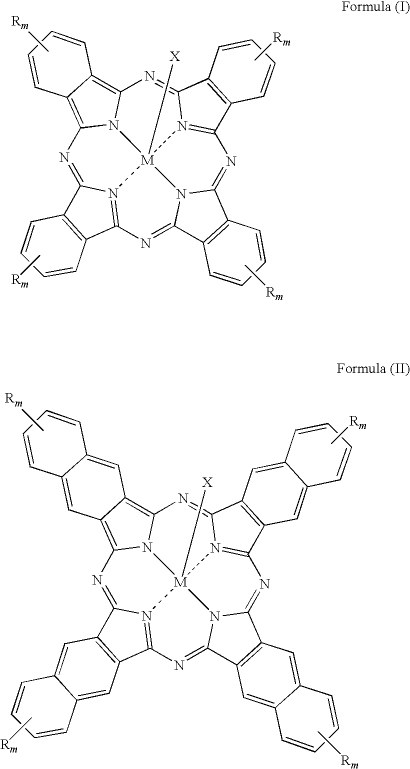

wherein M is a trivalent metal atom; each m represents the number of R substituents on the respective phenyl or naphthyl ring, and is independently an integer from 0 to 6; each R is independently selected from the group consisting of halogen, alkyl, substituted alkyl, alkoxy, substituted alkoxy, phenoxy, phenylthio, aryl, substituted aryl, heteroaryl, —CN, and —NO₂; and X is a halogen atom. The complex of Formula (II) is also known as a naphthalocyanine.

With regards to the R substituents, alkyl and alkoxy groups generally contain from 1 to about 12 carbon atoms, while the aryl groups contain from about 6 to about 20 carbon atoms. They may be substituted with halogen, alkyl, alkoxy, and —OH groups, and combinations thereof.

In certain embodiments, the trivalent metal atom M may be selected from the group consisting of indium, manganese, antimony, iron, gallium, titanium, and aluminum. In specific embodiments, the halogen atom X is chlorine. In more specific embodiments, the trivalent metal atom M is indium, the halogen atom X is chlorine, and each m is zero.

In some embodiments, the halogen-coordinated metal phthalocyanine is a p-type semiconductor. Exemplary p-type halogen-coordinated metal phthalocyanines include those of Formulas (1) through (8) below:

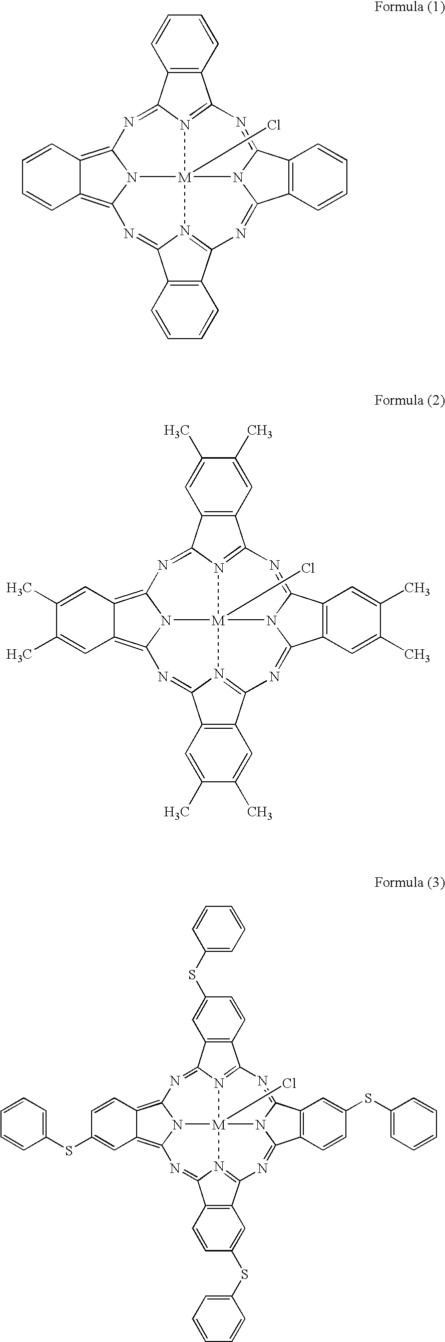

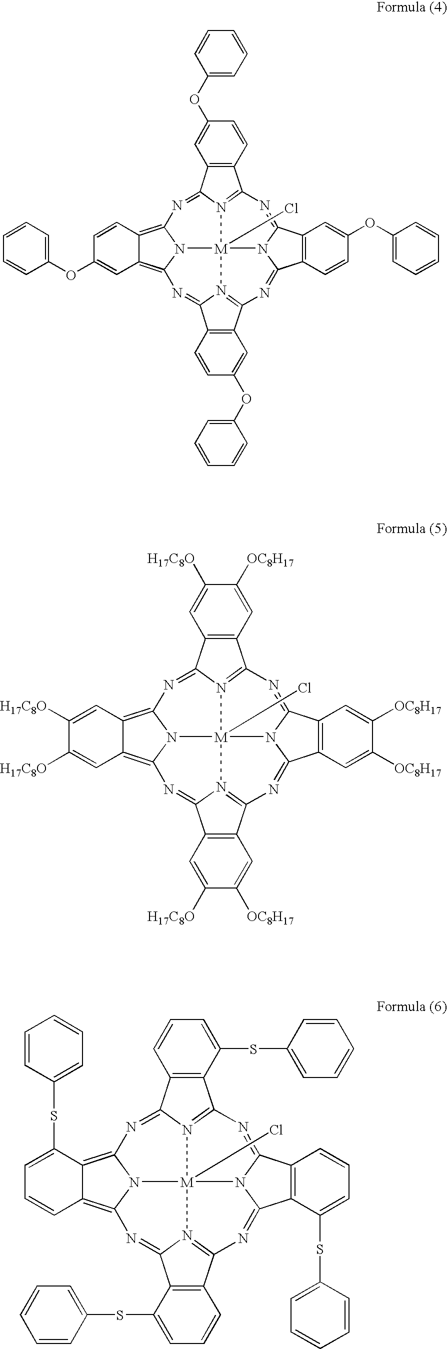

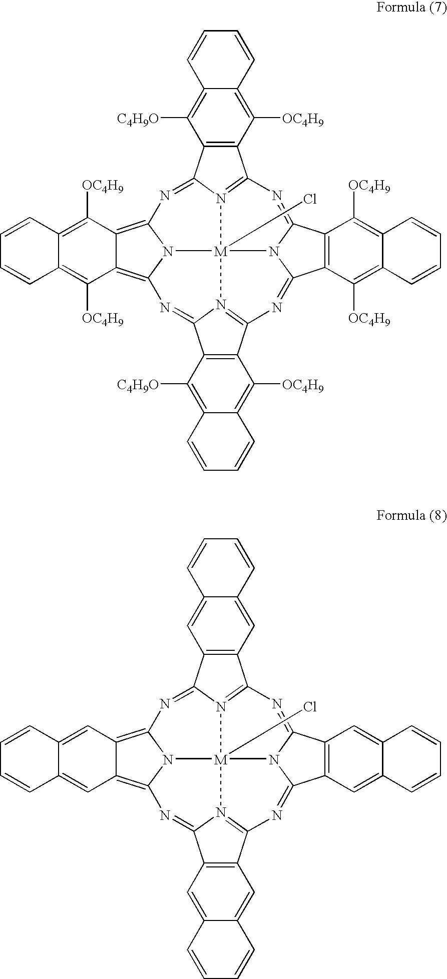

In further embodiments, the halogen-coordinated metal phthalocyanine is an n-type semiconductor. Exemplary n-type halogen-coordinated metal phthalocyanines are those shown in Formulas (9)-(11) below:

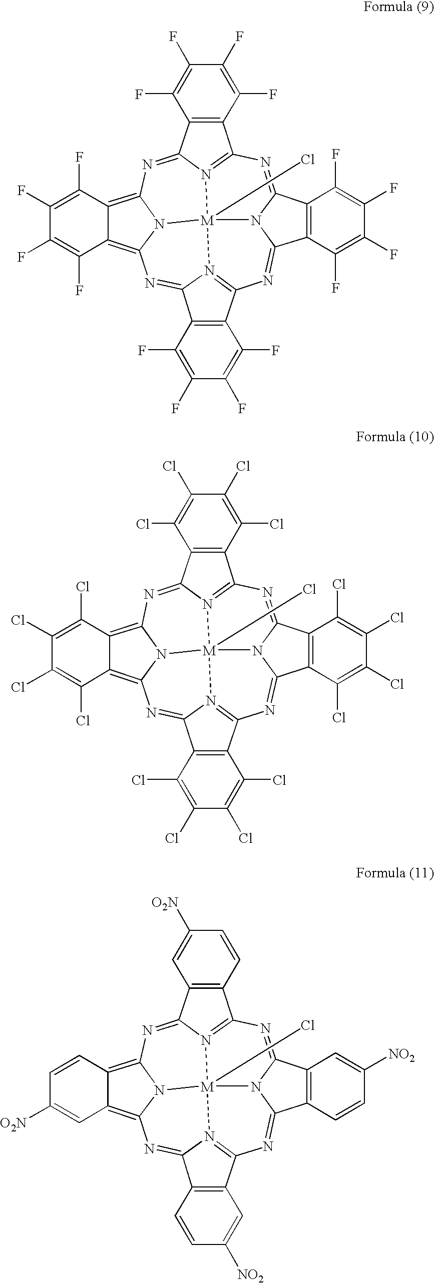

Previously, metal phthalocyanines with a divalent metal atom, such as copper, were used as semiconductors for thin film transistor applications. However, this metal phthalocyanine has some disadvantages. First, this metal phthalocyanine has low field effect mobility, typically less than 0.05 cm²/V·sec. Second, this metal phthalocyanine has very poor solubility when it is unsubstituted, which excludes possibilities for solution processing.

On the other hand, halogen-coordinated metal phthalocyanines containing a trivalent metal atom as disclosed here have dramatically enhanced mobility. The resulting transistor has the mobility of about 0.1 cm²V·sec or greater, including about 0.5 cm²/V·sec or greater. In other embodiments, the transistor has a current on/off ratio of about 10⁴ or greater, including 10⁵ or greater. Without being limited by theory, it is believed that the enhanced mobility of halogen-coordinated metal phthalocyanines is due to a different molecular packing in the semiconductor layer. Due to the coordination of the halogen atom at the center of the phthalocyanine ring, the halogen-coordinated metal phthalocyanine likely adopts a two-dimensional interlocking packing in the semiconductor layer. This two-dimensional interlocking packing is illustrated in Structures (A) and (B) as shown below:

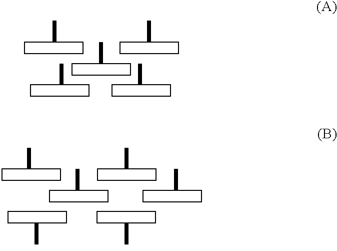

This interlocking two-dimensional packing enables sufficient pi-pi overlapping among phthalocyanine molecules in different layers, thus allowing more efficient charge transfer.

Another advantage of halogen-coordinated metal phthalocyanines is their enhanced solubility, which makes solution deposition processes feasible even for unsubstituted phthalocyanines (when each m is 0). Compared to copper phthalocyanine, the halogen-coordinated metal phthalocyanine has an improved solubility, for example at least 50%, or at least 100%. In embodiments, the halogen-coordinated metal phthalocyanine has a solubility of from about 0.01 to about 20 wt % in a suitable solvent, particularly a chlorinated solvent such as chlorobenzene, dichlorobenzene, trichlorobenzene, chlorotoluene, and the like. Other suitable solvents include toluene, xylene, tetrahydronaphthelene, mesitylene, aromatic esters, and the like.

The semiconducting layer may further comprise a polymer. Such polymers are known in the art and may include, for example, insulating and semiconducting polymers such as triarylamine polymers, polyindolocarbazole, polycarbazole, polyacenes, polyfluorene, polystyrene, polymethyl methacrylate, poly(vinyl cinnamate), poly(vinyl phenol), polycarbonate, or polythiophenes and their substituted derivatives.

In some embodiments, an interfacial layer is located between the semiconducting layer and the dielectric layer. The interfacial layer may improve via mobility of the transistor. In particular embodiments, the dielectric layer is formed from an alkyltrichlorosilane, having from about 4 to about 24 carbon atoms, including from about 6 to about 18 carbon atoms. Exemplary alkyltrichlorosilanes include octyltrichlorosilane and dodecyltrichlorosilane.

The halogen-coordinated metal phthalocyanine complex of Formula (I) may be synthesized using methods known in the art. Such complexes are commercially available from Aldrich, and they can then be purified using any suitable method such as sublimation. In embodiments, the halogen-coordinated metal phthalocyanine is sublimed at least twice at a vacuum pressure of 1.0×10⁻³ mbar or less.

The semiconducting layer is from about 5 nm to about 1000 nm thick, especially from about 10 nm to about 100 nm thick. The semiconducting layer can be formed by any suitable method, for example by vacuum deposition or liquid deposition. Liquid deposition processes include spin coating, dip coating, blade coating, rod coating, screen printing, stamping, ink jet printing, and the like, and other conventional processes known in the art.

In certain embodiments, the semiconductor layer is solution deposited. In some embodiments, the semiconductor layer consists of the halogen-coordinated metal phthalocyanine. The halogen-coordinated metal phthalocyanine is deposited from a solution. In other embodiments, the semiconductor layer comprises the halogen-coordinated metal phthalocyanine and a polymer. The semiconductor layer is formed by solution deposition of a liquid composition comprising a solvent, the halogen-coordinated metal phthalocyanine, and the polymer. The polymer is dissolved in the solvent in the liquid composition. The halogen-coordinated metal phthalocyanine may be partially dissolved in the solvent, and partially dispersed in the solvent.

The partially dispersed portion of the halogen-coordinated metal phthalocyanine complex may have a particle size of, for example, from about 10 nanometers to about 2000 nanometers, including about 20 to about 1000 nanometers. The weight ratio between the partially dissolved portion and the partially dispersed portion of the phthalocyanine complex may be from about 5:95 to about 80:20, including from about 10:90 to about 50:50. The weight ratio between the polymer and the halogen-coordinated metal phthalocyanine may be from about 1:99 to about 45:55, including from about 3:97 to about 10:90. In further embodiments, both the polymer and the halogen-coordinated metal phthalocyanine are dissolved in the solvent.

The substrate may be composed of materials including, but not limited to, silicon, glass plate, or a plastic film or sheet. For structurally flexible devices, plastic substrate, such as for example polyester, polycarbonate, polyimide sheets and the like may be used. The thickness of the substrate may be from about 10 micrometers to over 10 millimeters with an exemplary thickness being from about 50 micrometers to about 5 millimeters, especially for a flexible plastic substrate and from about 0.5 to about 10 millimeters for a rigid substrate such as glass or silicon.

The gate electrode is composed of an electrically conductive material. It can be a thin metal film, a conducting polymer film, a conducting film made from conducting ink or paste or the substrate itself, for example heavily doped silicon. Examples of gate electrode materials include but are not restricted to aluminum, gold, silver, chromium, indium tin oxide, conductive polymers such as polystyrene sulfonate-doped poly(3,4-ethylenedioxythiophene) (PSS-PEDOT), and conducting ink/paste comprised of carbon black/graphite or silver colloids. The gate electrode can be prepared by vacuum evaporation, sputtering of metals or conductive metal oxides, conventional lithography and etching, chemical vapor deposition, spin coating, casting or printing, or other deposition processes. The thickness of the gate electrode ranges from about 10 to about 500 nanometers for metal films and from about 0.5 to about 10 micrometers for conductive polymers.

The dielectric layer generally can be an inorganic material film, an organic polymer film, or an organic-inorganic composite film. Examples of inorganic materials suitable as the dielectric layer include silicon oxide, silicon nitride, aluminum oxide, barium titanate, barium zirconium titanate and the like. Examples of suitable organic polymers include polyesters, polycarbonates, poly(vinyl phenol), polyimides, polystyrene, polymethacrylates, polyacrylates, epoxy resin and the like. The thickness of the dielectric layer depends on the dielectric constant of the material used and can be, for example, from about 10 nanometers to about 500 nanometers. The dielectric layer may have a conductivity that is, for example, less than about 10-12 Siemens per centimeter (S/cm). The dielectric layer is formed using conventional processes known in the art, including those processes described in forming the gate electrode.

If desired, an interfacial layer may be placed between the dielectric layer and the semiconducting layer. As charge transport in an organic thin film transistor occurs at the interface of these two layers, the interfacial layer may influence the TFT's properties. Exemplary interfacial layers may be formed from silanes, such as those described in U.S. patent application Ser. No. 12/101,942, filed Apr. 11, 2008.

Typical materials suitable for use as source and drain electrodes include those of the gate electrode materials such as gold, silver, nickel, aluminum, platinum, conducting polymers, and conducting inks. In specific embodiments, the electrode materials provide low contact resistance to the semiconductor. Typical thicknesses are about, for example, from about 40 nanometers to about 1 micrometer with a more specific thickness being about 100 to about 400 nanometers. The OTFT devices of the present disclosure contain a semiconductor channel. The semiconductor channel width may be, for example, from about 5 micrometers to about 5 millimeters with a specific channel width being about 100 micrometers to about 1 millimeter. The semiconductor channel length may be, for example, from about 1 micrometer to about 1 millimeter with a more specific channel length being from about 5 micrometers to about 100 micrometers.

The source electrode is grounded and a bias voltage of, for example for a p-type semiconductor, about 0 volt to about 80 volts is applied to the drain electrode to collect the charge carriers transported across the semiconductor channel when a voltage of, for example, about +10 volts to about −80 volts is applied to the gate electrode. The electrodes may be formed or deposited using conventional processes known in the art.

If desired, a barrier layer may also be deposited on top of the TFT to protect it from environmental conditions, such as light, oxygen and moisture, etc. which can degrade its electrical properties. Such barrier layers are known in the art and may simply consist of polymers.

One advantage of a halogen-coordinated metal phthalocyanine semiconductor is its excellent stability under ambient conditions. In embodiments, the semiconductor is stable under ambient oxygen and humidity over 1 month, or over 3 months, or over 6 months.

The various components of the OTFT may be deposited upon the substrate in any order, as is seen in the Figures. The term “upon the substrate” should not be construed as requiring that each component directly contact the substrate. The term should be construed as describing the location of a component relative to the substrate. Generally, however, the gate electrode and the semiconducting layer should both be in contact with the dielectric layer. In addition, the source and drain electrodes should both be in contact with the semiconducting layer. The semiconducting polymer formed by the methods of the present disclosure may be deposited onto any appropriate component of an organic thin-film transistor to form a semiconducting layer of that transistor.

The following examples illustrate an OTFT made according to the methods of the present disclosure. The examples are merely illustrative and are not intended to limit the present disclosure with regard to the materials, conditions, or process parameters set forth therein. All parts are percentages by weight unless otherwise indicated.

### EXAMPLE

Indium phthalocyanine chloride was synthesized and sublimed once before use. Experimental bottom-gate transistors, similar to FIG. 3, were built on an n-doped silicon wafer acting as the substrate and the gate electrode with a 200-nm thick thermal silicon oxide (SiO₂) layer as the dielectric layer. The SiO₂ surface was first modified with a self-assembled monolayer (SAM) of octadecyltrichlorosilane (OTS-18) by immersing a clean wafer substrate in 0.1 M OTS-18 solution in toluene at 60° C. for 20 minutes. The OTS-18 SAM was used to direct and facilitate molecular self-organization during semiconductor deposition. A 60-nm thick semiconducting layer of indium phthalocyanine chloride was deposited on the OTS-18 interfacial layer by vacuum evaporation at a rate of 0.5 angstrom/second with a substrate temperature of 160° C. Subsequently, gold source-drain electrode pairs were deposited on the semiconductor layer through a shadow mask, thus creating a series of OTFTs with various channel lengths (L) and widths (W). Patterned transistors with a channel length of 90 or 190 μm and channel width of 1 or 5 mm were used for current/voltage measurements.

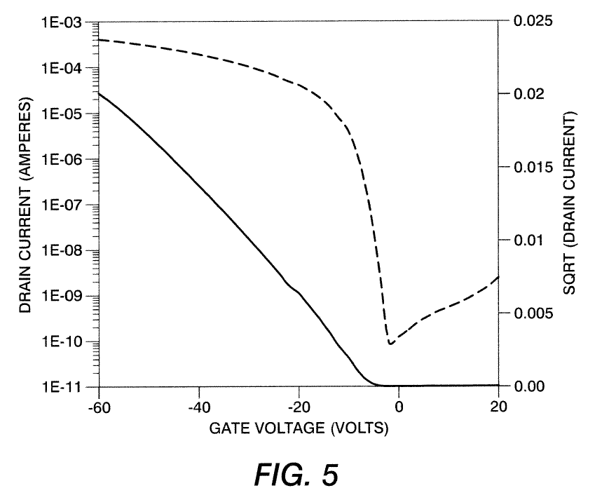

FIG. 5 shows the transfer curve of a typical OTFT device having a width of 5 mm and a length of 90 μm. The solid line (on the left) is the square root of the drain current and the dotted line (on the right) is the drain current. Note that the y-axis for the drain current is logarithmic, whereas the square root of the drain current is linear. The transistor exhibited field effect mobility of up to 0.52 cm²/V·sec with a current on/off ratio greater than 10⁶. The mobility value is more than one order of magnitude higher than a metal phthalocyanine such as copper phthalocyanine. Without being limited by theory, the difference may be because copper phthalocyanine is planar, whereas the halogen coordinated metal phthalocyanine complexes of the present disclosure are not. This difference affects the molecular packing of the semiconducting layer.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A thin-film transistor comprising a semiconducting layer, wherein the semiconducting layer comprises a halogen-coordinated metal phthalocyanine complex of Formula (I) or Formula (II): 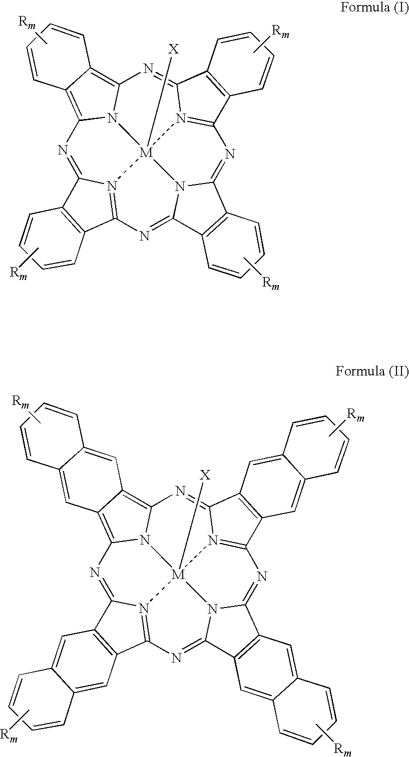
wherein M is a trivalent metal atom;
each m represents the number of R substituents on the phenyl or naphthyl ring, and is independently an integer from 0 to 6;
each R is independently selected from the group consisting of halogen, alkyl, substituted alkyl, alkoxy, substituted alkoxy, phenoxy, phenylthio, aryl, substituted aryl, heteroaryl, —CN, and —NO₂; and
X is a halogen atom.

2. The transistor of claim 1, wherein M is selected from the group consisting of indium, antimony, iron, titanium, manganese, gallium, and aluminum.

3. The transistor of claim 1, wherein the halogen-coordinated metal phthalocyanine complex is selected from Formulas (1) to (11):

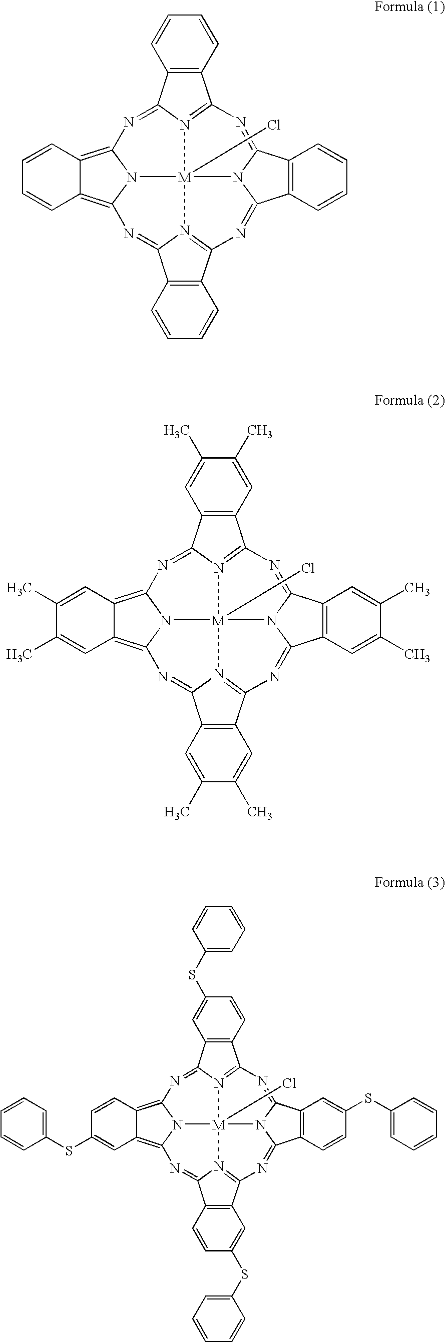

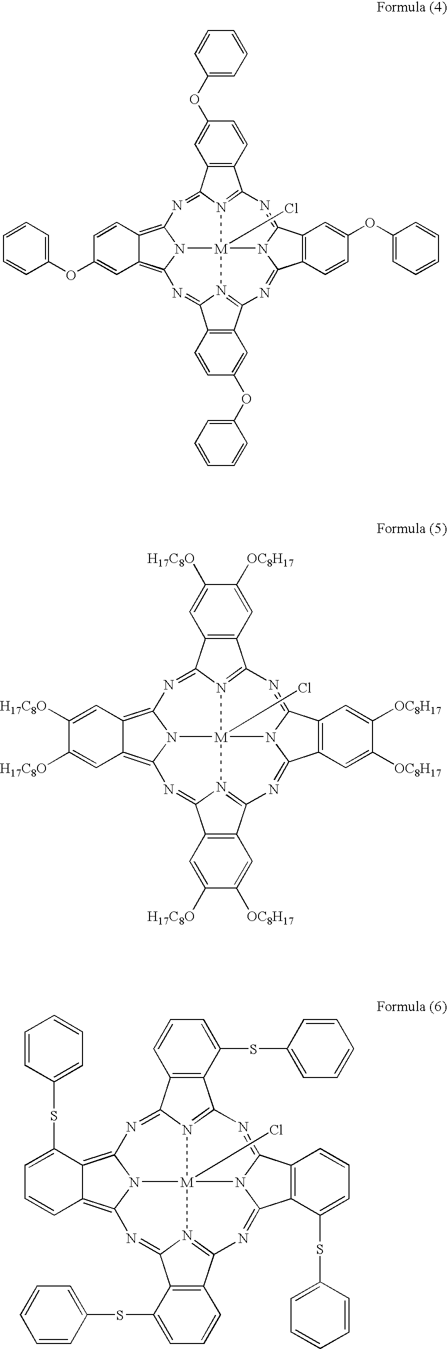

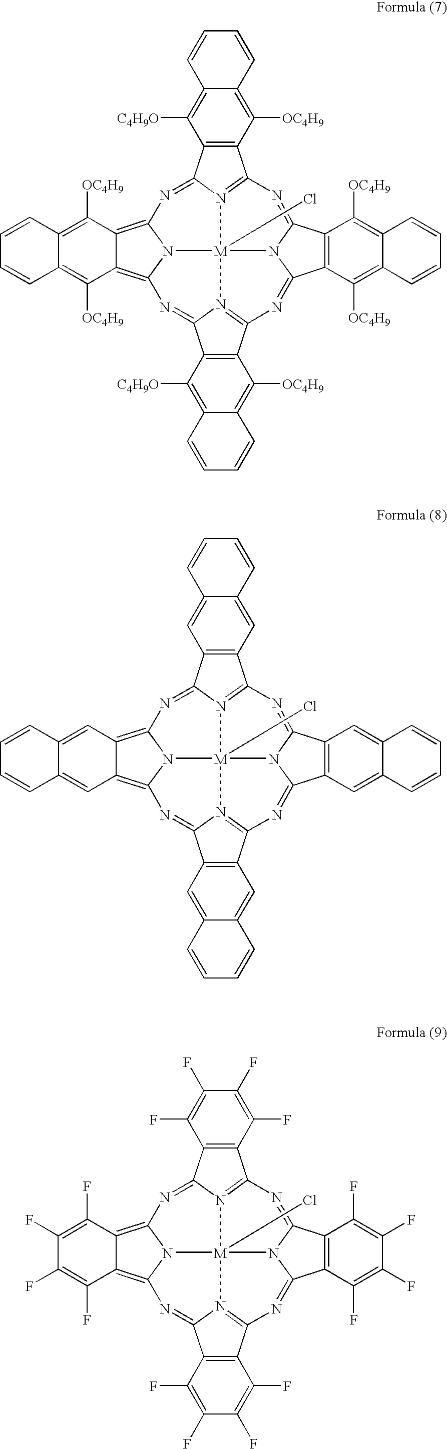

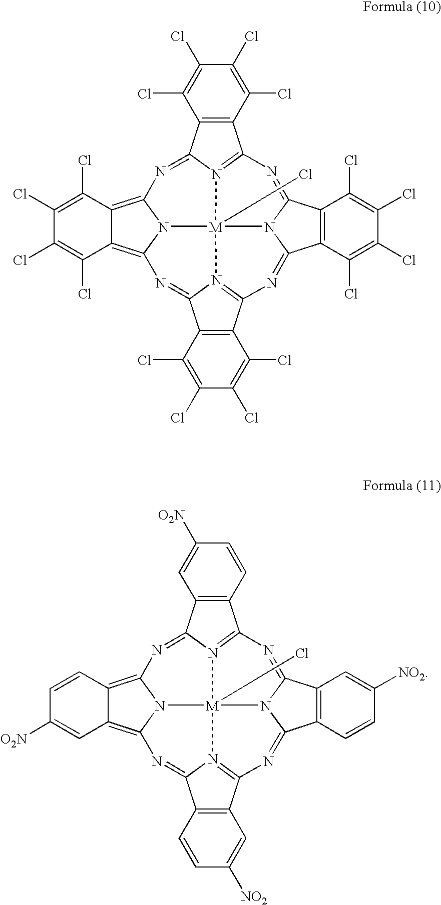

4. The transistor of claim 1, wherein the halogen atom X is chlorine.

5. The transistor of claim 1, wherein the trivalent metal atom M is indium, the halogen atom X is chlorine, and each m is zero.

6. The transistor of claim 1, wherein the transistor has a mobility of about 0.1 cm²/V·sec or greater.

7. The transistor of claim 1, wherein the transistor has a current on/off ratio of about 10⁴ or greater.

8. The transistor of claim 1, wherein the semiconducting layer further comprises a polymer.

9. The transistor of claim 8, wherein the polymer is selected from the group consisting of triarylamine polymers, polyindolocarbazole, polycarbazole, polyacenes, polyfluorene, polystyrene, polymethyl methacrylate, poly(vinyl cinnamate), poly(vinyl phenol), polycarbonate, polythiophene, and polythiophene derivatives.

10. The transistor of claim 1, further comprising an interfacial layer located between the semiconducting layer and a dielectric layer.

11. The transistor of claim 10, wherein the interfacial layer is formed from an alkyltrichlorosilane having from about 4 to about 24 carbon atoms.

12. The transistor of claim 1, wherein the halogen-coordinated metal phthalocyanine complex forms a two-dimensional interlocking structure.

13. A process of preparing a thin film transistor comprising:
depositing a liquid composition onto a substrate to form a semiconducting layer, the liquid composition comprising a solvent, a polymer, and a halogen-coordinated metal phthalocyanine complex of Formula (I) or Formula (II): 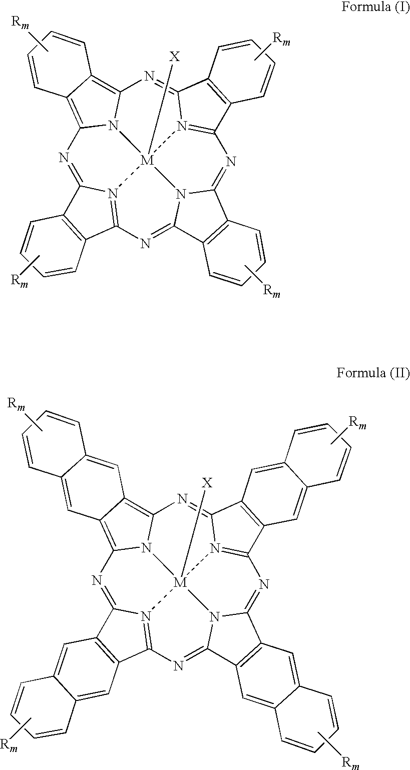
wherein M is a trivalent metal atom;
each m represents the number of R substituents on the phenyl or naphthyl ring, and is independently an integer from 0 to 6;
each R is independently selected from the group consisting of halogen, alkyl, substituted alkyl, alkoxy, substituted alkoxy, phenoxy, phenylthio, aryl, substituted aryl, heteroaryl, —CN, and —NO₂; and
X is a halogen atom.

14. The process of claim 13, wherein the halogen-coordinated metal phthalocyanine complex is partially dissolved in the solvent and partially dispersed in the solvent.

15. The process of claim 14, wherein the weight ratio between the dissolved portion and the dispersed portion of the metal phthalocyanine complex is from about 5:95 to about 80:20.

16. The process of claim 14, wherein the partially dispersed portion of the halogen-coordinated metal phthalocyanine complex has a particle size of from about 10 nanometers to about 2000 nanometers.

17. The process of claim 13, wherein the halogen-coordinated metal phthalocyanine complex and the polymer are dissolved in the solvent.

18. The process of claim 13, wherein the solvent is a chlorinated solvent selected from the group consisting of chlorobenzene, dichlorobenzene, trichlorobenzene, and chlorotoluene.

19. The process of claim 13, wherein M is selected from the group consisting of indium, antimony, iron, titanium, manganese, gallium, and aluminum.

20. The process of claim 13, wherein the polymer is selected from triarylamine polymers, polyindolocarbazole, polycarbazole, polyacenes, polyfluorene, polystyrene, polymethyl methacrylate, poly(vinyl cinnamate), poly(vinyl phenol), polycarbonate, polythiophene, and polythiophene derivatives.
